(19) United States
(12) Patent Application Publication
(10) Pub. No.: US 2008/0056051 A1
(43) Pub. Date: Mar. 6, 2008

(54) MEMORY WITH MEMORY BANKS AND MODE REGISTERS AND METHOD OF OPERATING A MEMORY

(76) Inventors: Peter Mayer, Neubiberg (DE); Wolfgang Spirkl, Germering (DE); Markus Balb, Munich (DE); Christoph Bilger, Munich (DE); Martin Brox, Munich (DE); Thomas Hein, Munich (DE); Michael Richter, Ottobrunn (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/469,294

(22) Filed: Aug. 31, 2006

(51) Int. Cl. G11C 5/14; G11C 8/00

(52) U.S. Cl. 365/230.03; 365/226; 365/230.08

(57) ABSTRACT

Memory with at least two memory banks each having memory cells, a control circuit, and at least one bank mode register, wherein the bank mode register stores information about an operation mode of a memory bank, wherein the control circuit operates at least one of the memory banks according to the information of the mode register.

### BACKGROUND OF THE INVENTION

1. Field of the Invention

The present invention generally relates to microelectronic devices. More particularly, the invention relates to programmable structures suitable for various integrated circuit applications, for example, in memory devices.

2. Description of the Related Art

Memories, for example dynamic random access memories, include a memory controller that receives control signals. The memory controller includes a mode register in which an operation mode is stored. The memory controller controls memory operations such as for example reading data, writing data or refreshing data according to the control signals and the operation mode.

Thus, one operation mode is used for controlling the memory that may comprise different memory banks.

### SUMMARY OF THE INVENTION

One embodiment of the invention refers to a memory with at least two memory banks with memory cells, a control circuit, and at least one bank mode register. The bank mode register stores information about an operation mode of a memory bank. The control circuit operates at least one of the memory banks according to the information of the bank mode register.

Another embodiment of the invention refers to a memory with at least two memory banks with memory cells with at least one mode register. The mode register stores information about a power mode of a memory bank. The information is considered operating the memory bank.

A further embodiment refers to a method of operating a memory with at least two memory banks comprising memory cells, and at least one bank mode register storing an information about an operating mode of at least one of the memory banks. During the operation of the at least one memory bank the information of the mode register is considered.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic drawing of a DRAM;

FIG. 2 is a more detailed drawing of a DRAM;

FIG. 3 is a data group for programming the mode register; and

FIG. 4 shows a flow chart of an embodiment of a process using mode registers for the different memory banks.

### DETAILED DESCRIPTION OF THE PREFERRED EMBODIMENT

The present invention may be described in terms of various functional components. It should be appreciated that such functional components may be realized by any number of hardware or structural components configured to perform the specified functions. For example, the present invention may employ various integrated components comprised of various electrically devices, such as resistors, transistors, capacitors, diodes and such components, the behaviour of which may be suitably configured for various intended purposes. In addition, the present invention may be practised in any integrated circuit application where an effective reversible polarity is desired. Such general applications may be appreciated by those skilled in the art in light of the present disclosure are not described in detail. Further, it should be noted that various components may be suitably coupled or connected to other components within exemplary circuits, and that such connections and couplings can be realized by direct connection between components and by connections through other components and devices located in between.

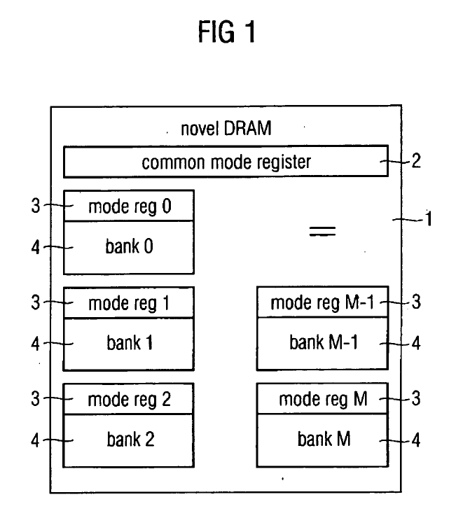

FIG. 1 depicts in a schematic drawing a memory 1 with a common mode register 2 and several bank mode registers 3. In the common mode register 2 data and information are stored that determine how to operate the memory depending on control signals. The data and/or information of the common mode register 2 may be used for all memory banks.

The bank mode registers 3 comprise data and/or information that determine how to operate a part of the memory, for example, a determined memory bank. The memory may comprise several memory banks 4. Using this embodiment, it is possible to operate different parts of the memory, for example different memory banks, with different operations although the same control signals are applied to the memory 1. In one embodiment, a separate bank mode register is provided for every memory bank, wherein each bank mode register includes data and/or information that is used only for the dedicated memory bank.

Thus, it is possible to operate the memory banks separately, which may improve a power management of the memory, according to one embodiment.

For reducing power consumption of the memory, some memory banks 4 may be completely disabled and the power supply shut off. Furthermore, the different memory banks 4 may be supplied with different power voltages. Furthermore, an access latency for accessing the memory cells of the memory banks 4 may be different for the different memory banks. The memory banks 4 with a short access latency consume more power than slow banks with a larger access latency. Thus it might be of advantage to store data that are used for a slower processing operation in a memory bank with the relatively increased access latency and the data that are used for fast operation processes are stored in the memory bank with a relatively reduced access latency.

In a further embodiment, the operation of the memory banks 4 may differ in a page length and a number of data that are prefetched for reading data from the memory of the memory bank. A high prefetch operation is associated with a long page length and high power consumption. Thus, it might save power if some memory banks 4 are operated with a smaller prefetch and a short page length. For example, accessing a first memory bank a page length of 1 kByte may be used with low power consumption and another memory bank may be accessed with a page length of 4 kByte with an increased power consumption. Also in a further embodiment, a burst length for reading data may be different for the different memory banks.

In a further embodiment, a combination of the above discussed embodiment may be applied to improve the operation of the memory for example to reduce the power consumption.

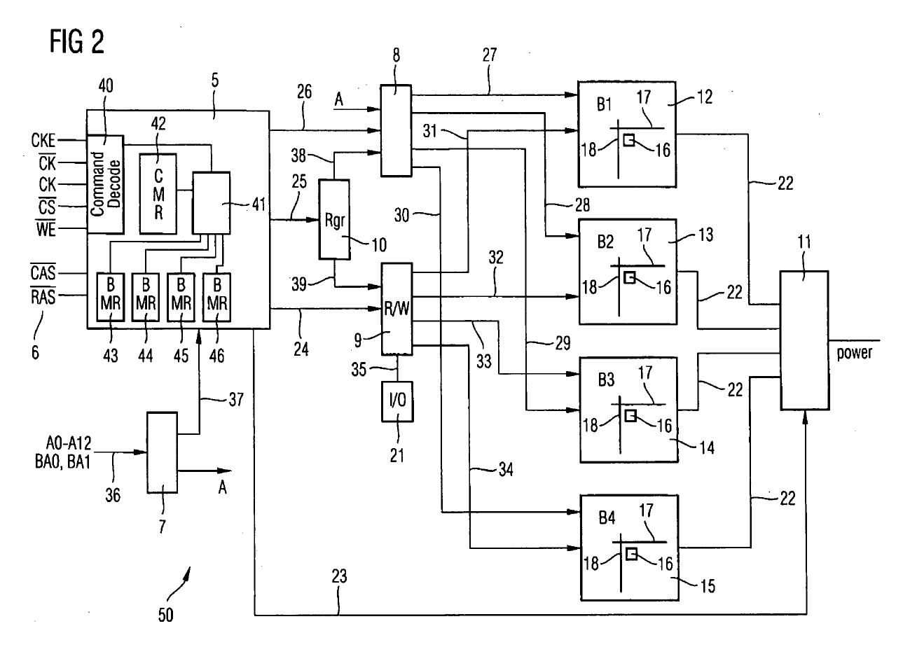

FIG. 2 depicts as an embodiment a dynamic random access memory 50 comprising a control unit 5 with signal input 6 that is connected with an address register 7, a select circuit 8, a read/write circuit 9, a refresh circuit 10 and a power supply 11.

The DRAM additionally includes four memory banks 12, 13, 14, 15 that include memory cells 16 that may be accessed using a word line 17 and a bit line 18.

The select circuit 8 is connected via select lines with each of the memory banks 12, 13, 14, 15. The read/write circuit 9 is connected with signal lines 20 with each of the memory banks 12, 13, 14, 15. Furthermore, the read/write circuit 9 is connected with an input/output circuit 21.

The power supply 11 supplies the memory banks 12, 13, 14, 15 with voltages via separate power lines 22.

The control unit 5 is connected via a first control line 23 with the power supply 11, via a second control line 24 with the read/write circuit 9, via a third control line 25 with the refresh circuit 10, and via a fourth control line 26 with the select circuit 8.

The select circuit 8 is connected via a first select line 27 with the first memory bank 12, via a second select line 28 with the second memory bank 13, via a third select line 29 with the third memory bank 14 and via a fourth select line 30 with the fourth memory bank 15. The read/write circuit 9 is connected via the first data line 31 with the first memory bank 12, via a second data line 32 with the second memory bank 13, via a third data line 33 with the third memory bank 14 and via a fourth data line 34 with the fourth memory bank 15.

The read/write circuit 9 is connected via a data path 35 with the input/output circuit 21. The address register 7 comprises an address input 36 and an address line 37 that is connected with the control unit 5. The refresh circuit 10 is connected via a further data line 38 with the select circuit 8 and via a second further data line 39 with the read/write circuit 9.

The control unit 5 comprises a command decoder circuit 40 that is connected with the signal input 6. Furthermore, the control unit 5 comprises a control circuit 41 that is connected with a common mode register 42, a first, a second, a third and a fourth bank mode register 43, 44, 45, 46. The common mode register 42 and the bank mode registers 43, 44, 45, 46 may comprise several data bits that determine different operation modes for operating the DRAM.

In the common mode register 42 operation features are determined, that may be common for all memory banks 12, 13, 14, 15.

The first bank mode register 43 comprises data and/or information that determine operation features of the first memory bank 12. The second bank mode register 44 comprises data and/or information that determine operation features of the second memory bank 13. The third bank mode register 45 comprises data and/or information that determine operation features of the third memory bank 14. The fourth bank mode register 46 comprises data and/or information that determine operation features of the fourth memory bank 15.

To control operations of the first, second, third or fourth memory bank 12, 13, 14, 15 the control circuit 41 considers data that are stored in the common mode register 42 and/or data that are stored in the first and/or second and/or third and/or fourth bank mode register 43, 44, 45, 46. In general, the control circuit 41 receives control commands from the command decoder 40. The command decoder 40 receives input signals via the signal input 6 and evaluates the input signals and generates control commands that are delivered to the control circuit 41.

Thus, it is possible to perform for example a reading operation or a writing operation or a refreshing operation differently for the first, the second, the third and the fourth memory bank 12, 13, 14, 15. Additionally, the control circuit 41 considers the data and/or information of the common mode register 42 and the first and/or the second and/or the third and/or the fourth bank mode register 43, 44, 45, 46 to control the power supply 11 differently for the different memory banks.

The common mode register 42 and the first, second, third and fourth bank mode register 43, 44, 45, 46 may be programmed by data that are received via the address input 36 and delivered from the address register 7 to the control unit 5. Thus it may be possible to change the data of the common mode register 42 and the data of the bank mode registers 43, 44, 45, 46.

In a further embodiment, the data of the common mode register 42 and the data of the bank mode registers 43, 44, 45, 46 are stored permanently and may not be changed during an operation of the DRAM 50.

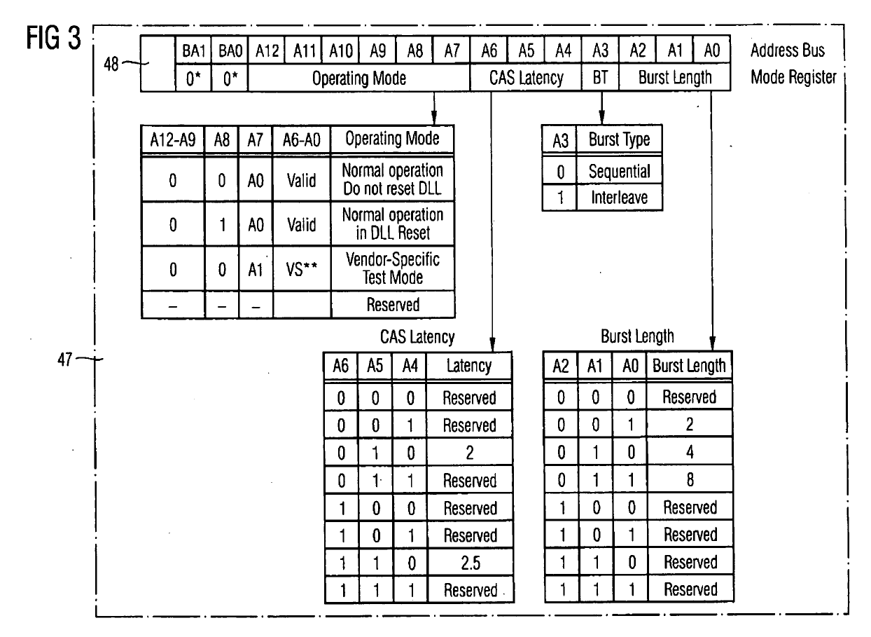

FIG. 3 depicts a program data group 47 that is received by the address register 7. The program data group 47 comprises thirteen data bits that determine operating features of the memory. Additionally, the program data group 47 comprises a first and a second enabling bit BA1, BA0 that determine whether a programming should be performed by the control circuit 41 receiving the program data group 47. Furthermore, the program data group 47 comprises register bits 48 that determine which of the mode registers (i.e., the common mode register 42, the first, the second, the third or the fourth bank mode register 43, 44, 45, 46) may be programmed using the program data group 47. As it is depicted in FIG. 3, the first, the second and the third data bit A0, A1, A2 refer to a burst length. The fourth data bit A3 refers to a burst type, the fifth, sixth and seventh data bit A4, A5, A6 refer to a CAS latency, the eighth up to the twelfth data bit A7-A12 refers to an operating mode.

In the depicted embodiment, the burst type may be selected between a sequential burst and an interleave burst, according to which the first, second, third and fourth memory bank are accessed in a sequential queue or are accessed in an interleaved method, respectively.

The burst length can be adapted by the first, second and third data bit A0, A1, A2 of the program data group as depicted to a length of two, four or eight data bits. Depending on the embodiment, other lengths of burst may be selected.

The three data bits A4, A5, A6 referring to the CAS latency may determine different values of CAS latency. In the shown embodiment, the CAS latency is selected from 2 and 2.5 of a duty cycle. The operating mode may be determined as a normal operation without a reset of a delay locked loop circuit or as a normal operation with a reset of the delay locked loop or as a vendor specific test mode.

The data bits starting with the eighth data bit A7 up to the thirteenth data bit A12 may be used to determine different operation modes for the different memory banks. For example, it may be determined that the first or second or third or fourth memory bank 12, 13, 14, 15 may be completely disabled and disconnected from the power supply 11. Furthermore, it may be determined that for storing data in a memory bank, a twin cell operation mode is used, meaning that two memory cells are used for storing data in the memory bank. This operation is faster and more secure compared to a one memory cell storing, and the retention time is increased. Furthermore, twin cell operation mode reduces the self refresh current that is used for refreshing the storage of the memory elements.

Additionally, with the operating mode it may be determined, that the different memory banks are supplied with different individual voltage levels. Thus it is possible to supply each memory bank with an individual set of voltages.

The different memory banks may be operated with different CAS latencies, meaning with different times between two subsequent data accesses. Thus, the DRAM may comprise faster and slower memory banks, whereby the faster memory banks operate with a short latency but consume more power. The slower memory banks operate with a longer latency but consume less power.

Read and write accesses to the DRAM may be burst oriented, with a burst length being programmable. The burst length determines the maximum number of column locations that can be accessed for a given read or write command. Burst length of two, four, or eight locations are available for both the sequential and the interleaved burst types. Thus it may be possible to use different burst lengths for different memory banks. When a read or write command is issued, a block of columns equal to the burst length is effectively selected. All accesses for that burst take place within this block, meaning that the burst wraps within the block if a boundary is reached. Accesses within a given burst may be programmed to be other sequential or interleaved. The ordering of accesses within a burst is determined by the burst length, the burst type and the starting column address.

A CAS latency is the delay in clock cycles between the registration of a read command and the availability of the first burst of output data. The latency may be programmed to different values, for example, 2 or 2.5 clocks. If a read command is registered at a clock edge n, and the latency is m clocks, the data is available nominally coincident with clock edge n plus m.

The operating mode is programmed by receiving a program data group 47 with the first and second program bit BA1 and BA0 with a zero value. The register bits 48 of the program data group 47 indicate which of the bank mode register is to be programmed. The programming may refer to an operating mode, to a CAS latency, to a burst type, to a burst length or any other feature operating a memory bank 12, 13, 14, 15.

Other features may refer to a function including an enable or a disable of a delay locked loop (DLL) of the memory or controlling an output drive strength. The programmed data are stored in the bank mode registers until the registers are programmed again or the memory loses power. In normal operation, the DLL is enabled. The DLL enable is required during power-up initialization, and upon returning to normal operation after having disabled the DLL for the purpose of debug or evaluation. The DLL is automatically disabled when entering self-refresh operation and is automatically re-enabled upon exit of self-refresh operation. Any time the DLL is enabled, 200 clock cycles must occur before a read command can be issued.

A normal drive strength may be programmed for all outputs. An option for a weak driver support intended for light a load and/or point-to-point environment may be useful and programmed for single memory banks.

A further operating mode that may be programmed using data of the bank mode register may be a refresh operation of the memory. The refresh operation is used during normal operation of a memory to refresh data that are stored in the memory cells 16. Features of the refresh operating that may be programmed by the bank mode register may be the time interval between two refresh cycles and the addresses of memory cells that are refreshed. Thus, the bank mode registers allow for an improved efficiency in scheduling and switching the refresh operation. Furthermore, self-refresh operation may be performed for retaining data and the memory, even if the rest of the memory is powered down. When in the self-refresh mode, the memory retains data without external clocking. The self-refresh command is initiated as an autorefresh command coincident with a CKE transitioning low. The DLL is automatically disabled upon entering self-refresh, and is automatically enabled upon exiting self-refresh.

A further operating mode that may be determined by the bank mode registers individually for the different memory banks 12, 13, 14, 15 may be the power supply. Depending on the stored data in the bank mode register, the control unit 5 controls the power supply 11 to supply an individual power to the first, second, third and/or fourth memory bank 12, 13, 14, 15.

The control unit 5 delivers the program data referring to the refresh operation to the refresh circuit 10 that refreshes the stored data of the first, second, third and fourth memory bank 12, 13, 14, 15 individually according to the stored data of the bank mode registers 43, 44, 45, 46.

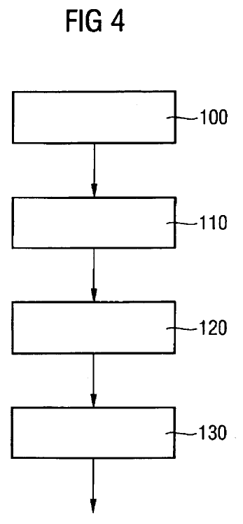

FIG. 4 depicts a schematic view of a program flow that is performed during the operation of the memory. At a program point 100, the memory 1 is initialized and a power supply 11 starts supplying power to the memory. In a following program point 110, the control unit 5 checks whether new program data are received from the address register 7. If there are new program data received, then the control circuit 41 checks the program data group 47 and programs the common mode register 42 and/or the first, the second, the third and/or the fourth bank mode register 43, 44, 45, 46 accordingly. If there is no new program data received, the stored data of the common mode register 42 and the first, the second, the third and the fourth bank mode register 43, 44, 45, 46 are used for operating the first, the second, the third and the fourth memory bank 12, 13, 14, 15.

In a following program point 120, the supply to the first, the second, the third and the fourth memory bank 12, 13, 14, 15 is controlled accordingly to the stored data of the first, the second, the third and the fourth bank mode register 43, 44, 45, 46. Depending on the used embodiment, also the common mode register 42 may be considered. This means that depending on the stored program data, the different memory banks may be supplied with different voltage levels and/or current values. For example the memory banks may be powered down individually or supplied with different levels of voltage.

At a following program point 130, the control unit 5 receives a clock enable signal CKA, a clock signal C̅K̅, an inverse clock signal CK, an inverse column signal C̅S̅, an inverse write enable signal W̅E̅, an inverse column access signal C̅A̅S̅, and an inverse row access signal R̅A̅S̅. The signals are received at the signal input 6 and are used for reading or writing data from or to the memory banks 12, 13, 14, 15. Additional to the controlling signals of the signal input 6, the control circuit 41 considers data that are stored in the common mode register 42 and in the first, second, third and fourth bank mode register 43, 44, 45, 46. The data of the bank mode register 43, 44, 45, 46 are individually assigned to the individual first, second, third and fourth memory bank 12, 13, 14, 15. Thus it is possible to operate the reading, writing, refreshing and the power supply of the different memory banks 12, 13, 14, 15 individually. The first bank mode register may be assigned to the first memory bank. The second bank mode register may be assigned to the second memory bank. The third bank mode register may be assigned to the third memory. The fourth bank mode register may be assigned to the fourth memory.

Thus, for example, a latency time for a column access, a number of data for a prefetch operation, a page length for a prefetch operation may be different for the different memory banks 12, 13, 14, 15.

While the foregoing is directed to embodiments of the present invention, other and further embodiments of the invention may be devised without departing from the basic scope thereof, and the scope thereof is determined by the claims that follow.

1. A memory, comprising:
at least two memory banks each with respective memory cells;
a control circuit; and
at least one bank mode register, wherein the bank mode register stores information about an operation mode of a particular one of the at least two memory banks, the information comprising a value of a supply voltage that is applied to the particular memory bank, wherein the control circuit operates the particular memory bank according to the information of the bank mode register.

2. (canceled)

3. The memory of claim 1, wherein the bank mode register stores information about a voltage level of a voltage terminal of the particular memory bank.

4. The memory of claim 1, wherein the bank mode register stores an information about an operating mode of the memory cells, the operating mode of the memory cells specifying whether to use one or two cells for storing a particular item of data in the particular memory bank.

5. The memory of claim 1. wherein the information specifies whether the particular memory bank is in a power on or a power down state.

6. The memory of claim 1, wherein the information specifies a latency time for access to the memory cells of the particular memory bank.

7. The memory of claim 1. wherein the information specifies a number of data of a prefetch operation for reading data from the particular memory bank.

8. The memory of claim 1, further comprising a common mode register configured to store common mode register information affecting operation of the memory and valid for the at least two memory banks.

9. A memory, comprising:
at least two memory banks each with respective memory cells; and
at least one bank mode register, wherein the bank mode register stores information about a power mode of a particular one of the at least two memory banks, wherein the information affects the operation of the particular memory bank.

10. The memory of claim 9, wherein the information specifies whether the particular memory bank is in a power on or a power down state.

11. A method of operating a memory, comprising:
providing the memory with at least two memory banks each comprising memory cells, and with at least one bank mode register storing an information about an operating mode of a particular one of the at least two memory banks, wherein the information soecifies a value of a supply voltaae for the particular memory bank; and
operating the particular memory bank according to the information of the mode register, wherein operating the particular memory bank comprises supplying the particular memory bank with a voltage specified by the information.

12. (canceled)

13. The method of claim 11, wherein the information specifies that a given item of data is to be stored by programming two memory cells in the particular memory bank and wherein operating comprises storing the given item of data by programming the two memory cells in the particular memory bank.

14. The method of claim 11, wherein the information specifies one of a power on state and a power off state of the particular memory bank and wherein operating comprises supplying the particular memory bank with power if the information specifies the power on state and supplying no power to the particular memory bank if the information specifies the power off state.

15. The method of claim 11, wherein the information specifies a value of an access latency for accessing the memory cells of the particular memory bank and wherein operating comprises accessing the memory cells of the particular memory bank with the access latency specified by the information.

16. The method of claim 11, wherein the information specifies a page length of a prefetch operation reading data from the memory cells of the particular memory bank and wherein operating comprises performing prefetch operations using the specified page length according to the information.
